(19) United States
(12) Patent Application Publication
(10) Pub. No.: US 2010/0182002 A1
(43) Pub. Date: Jul. 22, 2010

(54) MAGNETIC SENSOR DEVICE WITH FIELD GENERATOR AND SENSOR ELEMENT

(75) Inventors: Hans Van Zon, Eindhoven (NL); Johannes A.J.M. Kwinten, Eindhoven (NL); Josephus A.H.M. Kahlman, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/528,085

(22) PCT Filed: Feb. 19, 2008
(86) PCT No.: PCT/IB08/50585

§ 371 Date: Mar. 8, 2010

(30) Foreign Application Priority Data
Feb. 23, 2007 (EP) 07102971.4

(51) Int. Cl. G01R 33/02

(52) U.S. Cl. 324/244

(57) ABSTRACT

The invention relates to a magnetic sensor device (100) that can for example be used for the detection of magnetized particles (1) and that comprises at least one conductor (111, 113) and at least one magnetic sensor element, e.g. a GMR element (112). To compensate for their different thicknesses (d, h), these components are placed on a first and second region (R1, R2), respectively, that have different distances from a sensitive plane (E) of the magnetic sensor element (112). Thus a magnetic excitation field (H) generated by the conductor (111, 113) can be made perpendicular to said sensitive plane (E) in the magnetic sensor element (112). In a preferred production process, the conductor (111, 113) is for example partially embedded in a channel that is etched into the surface of a substrate (114).

The invention relates to a magnetic sensor device comprising a magnetic sensor element, particularly a magneto-resistive wire, and at least one conductor for the generation of magnetic excitation fields. Moreover, it relates to a method for the production and the use of such a sensor device.

From the WO 2005/010543 A1 and WO 2005/010542 A2 a magnetic sensor device is known which may for example be used in a microfluidic biosensor for the detection of (e.g. biological) molecules labeled with magnetic beads. The microsensor device is provided with an array of sensor units comprising wires for the generation of a magnetic field and Giant Magneto Resistance devices (GMRs) for the detection of stray fields generated by magnetized beads. The resistance of the GMRs is then indicative of the number of the beads near the sensor unit.

In the aforementioned documents, the wires and the GMR devices are assumed to have the same thickness and to be arranged on a common plane. In practice, the thicknesses of the wires and an associated GMR device may however substantially differ. Moreover, the sensitive plane of a GMR device does usually not coincide with the mid-plane of this device. The magnetic field generated by a current through the wires will therefore usually have a non-vanishing component in the sensitive plane of the GMR device that introduces a substantial magnetic cross-talk and thus corroborates the measurements of magnetized particles.

Based on this situation it was an object of the present invention to provide means for a more accurate determination of magnetic fields, particularly stray fields generated by magnetized particles.

This object is achieved by a magnetic sensor device according to claim 1, a method according to claim 7, and a use according to claim 11. Preferred embodiments are disclosed in the dependent claims.

The magnetic sensor device according to the present invention comprises the following components:
a) A magnetic sensor element that is sensitive for magnetic field components in a sensitive plane and that has a first thickness orthogonal to said sensitive plane. In this context, the “sensitive plane” is a geometrical object and therefore infinitely extended in two dimensions. Due to its design, the magnetic sensor element comprises some sensitive region (e.g. the free layer in a GMR element) that is sensitive to (vector) components of a magnetic field which prevail in this sensitive region and which are parallel to the sensitive plane. A magnetic field that is only orthogonal to the sensitive plane will however generate no measurement signals in the magnetic sensor element.
b) At least one electrical conductor for generating a magnetic excitation field when a current flows through it, wherein said conductor has a second thickness orthogonal to the sensitive plane and wherein the second thickness is different from the first thickness of the magnetic sensor element. The term “magnetic excitation field” is used in this context primarily as a unique reference to the magnetic field generated by the conductor; moreover, it contains a hint to the function of said field in many applications, namely the excitation of magnetic particles in a sample.
While the following discussion will include the basic situation that there is only one conductor associated to one magnetic sensor element, many preferred embodiments of the device comprise an arrangement of two conductors with an associated magnetic sensor element between them. Moreover, the magnetic sensor device may comprise a plurality of sensor units that each comprise one or more conductors associated to one or more magnetic sensor elements.

The relative arrangement of the aforementioned magnetic sensor element and the conductor shall be such that the magnetic excitation field generated by the conductor is substantially perpendicular to the sensitive plane within the (sensitive region of the) magnetic sensor element. The magnetic field is considered in this respect to be “substantially perpendicular” to the sensitive plane if the magnetic field component in the sensitive plane of the sensor element is less than 2%, preferably less than 0.2% of the magnitude of the magnetic field. The deviation of the magnetic excitation field from an exact orthogonality will then have a negligible effect on the sensor output.

The described magnetic sensor device has the advantage to provide sensor signals of a high accuracy as the magnetic cross-talk produced by in-plane components of magnetic excitation fields is minimized or even completely cancelled. At the same time the magnetic sensor device allows the generation of strong magnetic excitation fields (as they are needed for a sufficient excitation of e.g. magnetic particles in a sample), which requires that the conductor can be dimensioned with a sufficient thickness irrespective of the thickness of the magnetic sensor element.

In a preferred embodiment of the magnetic sensor device, the magnetic sensor element and the conductor are arranged on a first region and a second region, respectively, wherein said regions lie on an isolating material and—geometrically—in planes that have different distances from the sensitive plane of the sensor device. The different heights of the isolation material can thus compensate the different thicknesses of the conductor and the magnetic sensor element in such a way that the effective current flow through the conductor lies in the sensitive plane.

In a preferred realization of the aforementioned embodiment, the second region lies on the bottom of a channel in a substrate, wherein the first region is typically a part of the residual surface of the substrate. Thus the conductor can be embedded or sunken in an (otherwise planar) surface of the substrate to compensate for a higher thickness with respect to the magnetic sensor element. It is particularly possible to embed parts of conductor wires in a substrate (e.g. in CMOS technology) thus that there is a substantially planar surface on which the residual components of the magnetic sensor device can be built.

In an alternative design, either the first or the second region may be the top of a rim on the surface of a substrate (wherein said surface comprises the other region). The rim will then lift the thinner component (usually the magnetic sensor element) to a height where the magnetic excitation field becomes orthogonal to the sensitive plane.

In general, the conductor and the magnetic sensor element may have any three-dimensional shape. In a preferred embodiment, the shape of the magnetic sensor element and/or of the conductor is however symmetrical with respect to the sensitive plane. Physical effects of the components are then also symmetrical with respect to the sensitive plane. The magnetic excitation field that is generated by the conductor must for example cross the sensitive plane orthogonally due to the requirement of symmetry (under the assumption that the magnetic field cannot have a sharp bend).

The three-dimensional shape of the magnetic sensor element and/or of the conductor usually corresponds to an elongated structure with uniform cross section perpendicular to its axial direction, wherein said cross section is for example rectangular or circular.

In many applications the (first) thickness of the magnetic sensor element is smaller than the (second) thickness of the conductor, because the conductor has to be made large enough to allow sufficiently high currents. In a preferred embodiment of the invention, the first thickness amounts to less than 70%, preferably to less than 50%, most preferably to less than 10% of the second thickness.

The magnetic sensor element may particularly comprise coils, Hall sensors, planar Hall sensors, flux gate sensors, SQUIDS (Superconducting Quantum Interference Devices), magnetic resonance sensors, magneto-restrictive sensors, or magneto-resistive elements of the kind described in the WO 2005/010543 A1 or WO 2005/010542 A2, especially a GMR (Giant Magneto Resistance), a TMR (Tunnel Magneto Resistance), or an AMR (Anisotropic Magneto Resistance) element.

The invention further relates to a method for the production of a microelectronic magnetic sensor device of the kind described above, wherein said method comprises the following steps which can be executed in arbitrary sequence, including a simultaneous execution of two or more of these steps:
a) The generation of a first region and a second region on an isolating material at the surface of a substrate wherein said first and second region have different heights with respect to said surface.
b) Deposition of a first material for the magnetic sensor element over the first region. The first material may optionally have a layered structure as it is for example required for a GMR element.
c) Deposition of a second material for the conductor over the second region.

The method may optionally comprise further steps that are familiar to a person skilled in the fabrication of integrated microelectronic devices. Thus the deposition of a particular material over a limited region of the substrate will usually comprise the deposition of this material on the complete surface of the substrate, the localized deposition of a mask on the resulting layer of material, the removal of the material outside the mask by etching it away where it is not masked, and finally the removal of the mask, leaving the material limited to the region of interest on the substrate.

By adjusting the different heights of the first and the second region, the magnetic sensor element and the conductor that will finally reside on these regions can be placed at any desired relative height. Thus it is particularly possible to arrange them such that the magnetic excitation field generated by the conductor will be perpendicular to the sensitive plane in the magnetic sensor element.

The generation of the first and the second region of different heights may be achieved in various ways. According to one alternative, the first and the second region are generated by etching an initially planar surface of the substrate, thus generating recesses in the substrate having a “negative height” with respect to the residual surface. This approach can further be differentiated with respect to the fraction of the surface of the substrate that is etched; thus it is possible to etch only a small fraction, thus creating channels in the substrate, or to etch a larger fraction, thus leaving isolated rims or islands of elevated substrate.

In another alternative, the first and the second region are generated by deposition of an isolating material on the planar surface of the substrate. Thus elevated regions with respect to the level of the original planar surface of the substrate can be created. As was already mentioned, the deposition of the isolating material may comprise its deposition over the whole surface of the substrate and the subsequent removal of this material where it is not desired. Alternatively, components that shall be located directly on the substrate surface can optionally be deposited there before the isolating layer is deposited. The isolating material may particularly be the same material as the substrate.

In another preferred embodiment of the method, the first material (of the magnetic sensor element) is deposited also on the second region (where the conductor is constructed) such that the conductor will finally comprise material of the magnetic sensor element. This is usually no problem as electrical conductivity is the only requirement for a material suited for the conductor. In a similar way, the second material of the conductor can be deposited also over the first region where the magnetic sensor element is constructed.

The invention further relates to the use of the magnetic sensor device described above for molecular diagnostics, biological sample analysis, and/or chemical sample analysis, particularly the detection of small molecules. Molecular diagnostics may for example be accomplished with the help of magnetic beads that are directly or indirectly attached to target molecules.

These and other aspects of the invention will be apparent from and elucidated with reference to the embodiment(s) described hereinafter. These embodiments will be described by way of example with the help of the accompanying drawings in which:

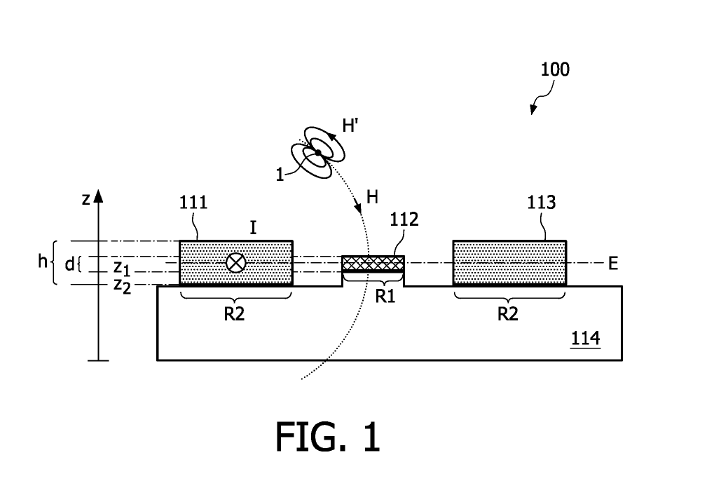

FIG. 1 is a schematic representation of a magnetic sensor device according to the present invention;

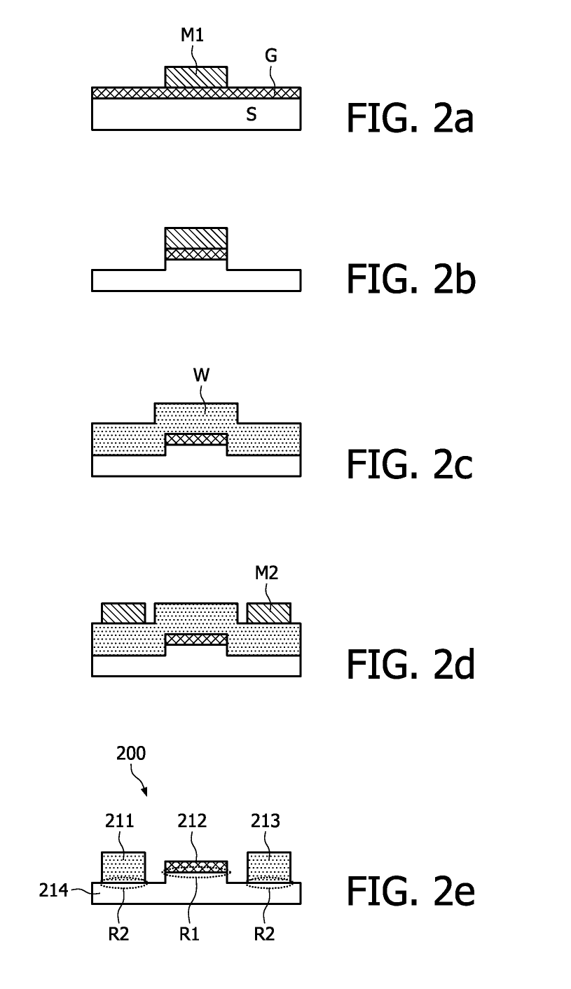

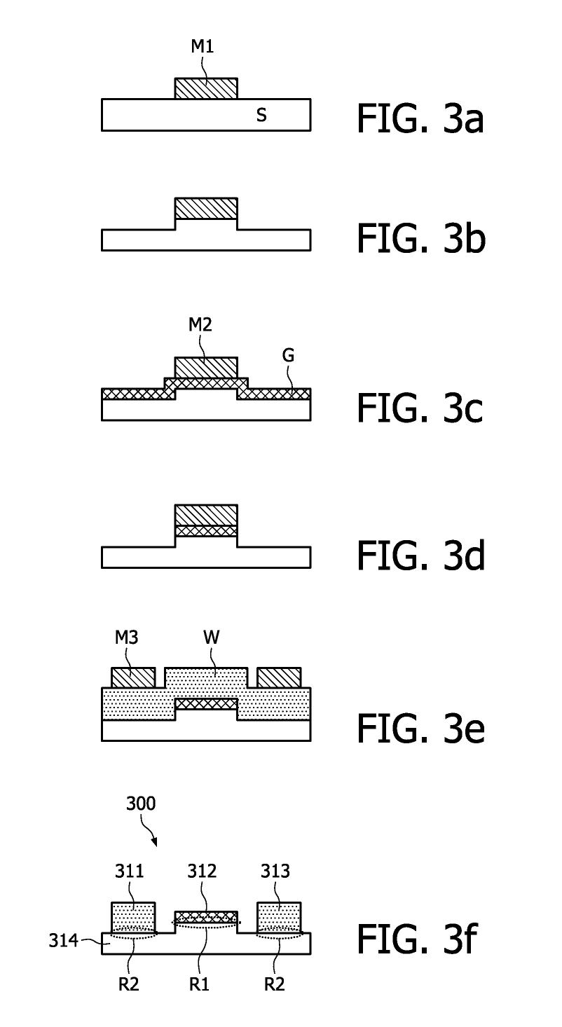

FIGS. 2 and 3 illustrate two alternative production processes of a magnetic sensor device that comprise the placement of a GMR element on an elevated region of a substrate;

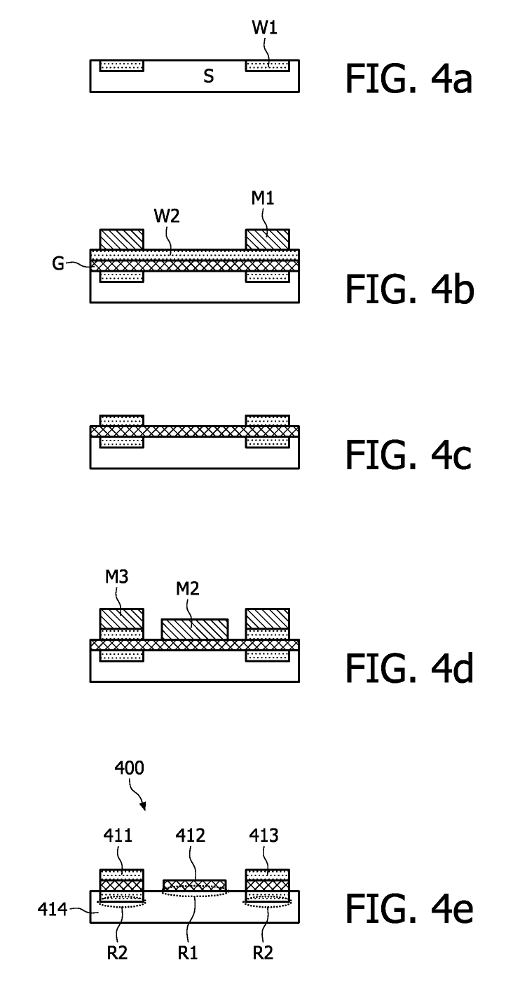

FIGS. 4, 5 and 6 illustrate three alternative production processes of a magnetic sensor device in which a part of the conductors is embedded in a substrate;

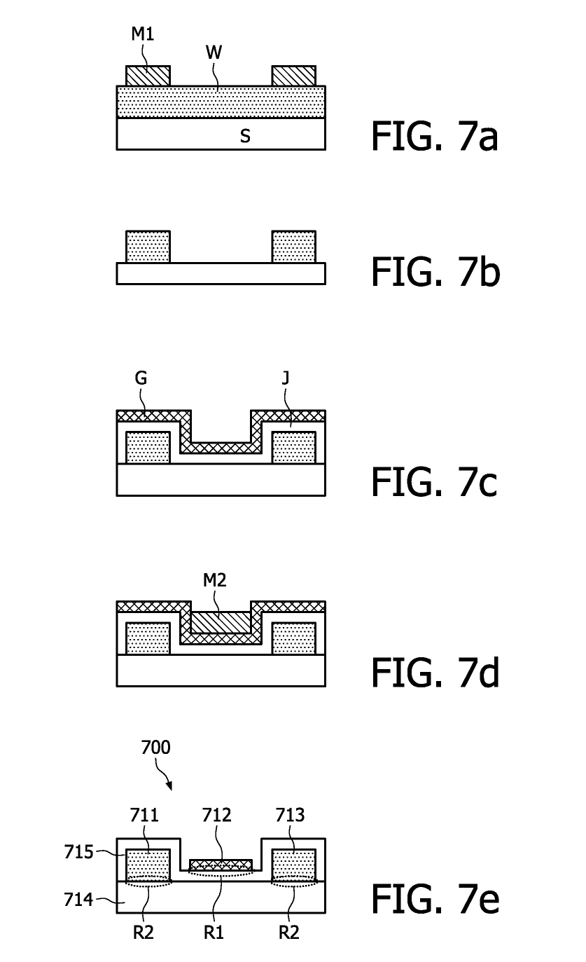

FIG. 7 illustrates a production process of a magnetic sensor device with an intermediate isolating layer;

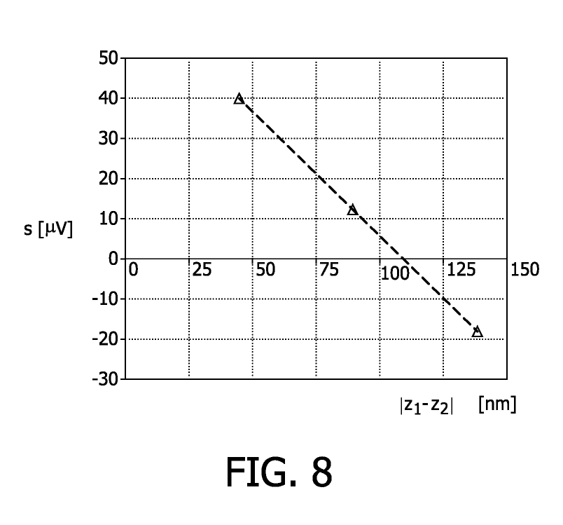

FIG. 8 shows the magnetic cross-talk signal s in a GMR element in dependence on the height difference of the regions on which the conductors and the GMR element, respectively, are placed.

Like reference numbers or numbers differing by integer multiples of 100 refer in the Figures to identical or similar components.

FIG. 1 illustrates a microelectronic magnetic sensor device 100 according to the present invention in the particular application as a biosensor for the detection of magnetically interactive particles, e.g. superparamagnetic beads 1 in an investigation region (sample chamber). Magneto-resistive biochips or biosensors have promising properties for bio-molecular diagnostics, in terms of sensitivity, specificity, integration, ease of use, and costs. Examples of such biochips are described in the WO 2003/054566, WO 2003/054523, WO 2005/010542 A2, WO 2005/010543 A1, and WO 2005/038911 A1, which are incorporated into the present application by reference.

A biosensor typically consists of an array of (e.g. 100) magnetic sensor devices 100 of the kind shown in FIG. 1 and may thus simultaneously measure the concentration of a large number of different target molecules (e.g. protein, DNA, amino acids, drugs of abuse) in a solution (e.g. blood or saliva). In one possible example of a binding scheme, the so-called “sandwich assay”, this is achieved by providing a binding surface with first antibodies to which the target molecules may bind. Superparamagnetic beads 1 carrying second antibodies may then attach to the bound target molecules. For simplicity, only the beads 1 are shown in the Figure.

A current I flowing in conductors in the form of excitation wires 111, 113 generates a magnetic field H, which then magnetizes the superparamagnetic beads 1. The stray field H′ from the superparamagnetic beads 1 introduces a magnetization component in the Giant Magneto Resistance (GMR) 112 of the sensor device 100 that has vector components in the sensitive plane E of the GMR 112 and therefore generates a measurable resistance change. This method is also applicable to other binding schemes (e.g. inhibition or competitive assays) to detect small molecules like drugs. Furthermore this method may also be used to detect (immobilized) magnetic beads at a certain distance from the sensor surface (bulk measurement).

Magneto-resistive sensors used in biosensors of the kind described above are usually very thin. Thus a typical thickness d of the GMR element 112 shown in FIG. 1 is for example in the order of several tens of nanometers, wherein said thickness is by definition measured in a direction z perpendicular to the surface of the device. Because the excitation wires have to generate a substantial magnetic excitation field H and thus have to conduct a substantial current I, the thickness h of the wires 111, 113 has to be chosen much larger, typically in the order of several hundreds of nanometers, in order to prevent excessive heating and/or electro-migration effects.

In a typical lithographical process, the magneto-resistive sensor element and the excitation wires are deposited onto a common planar surface of a substrate (not shown in the Figure). Due to their aforementioned difference in thickness, the center of the current in the excitation wires is then not exactly in the same plane as the sensitive layer of the magnetic sensor. This configuration causes that the magnetic field generated by the wires does not enter the sensitive region of the sensor element fully perpendicularly and thus a small in-plane component of the large excitation field is detected by the sensor. Due to the excitation field being much larger than the stray field of the beads, even the in-plane component of this field is much larger than the typical signals from the magnetic beads. This spurious in-plane component is referred to as the magnetic cross-talk signal which interferes with the signal to be measured. A configuration and a method are therefore required that reduce or completely eliminate this magnetic cross-talk signal such that the stray fields from the beads can be measured more reliably.

It is proposed here to solve the aforementioned problem of magnetic cross-talk by lowering the thick excitation wires 111, 113 with respect to the thin magneto-resistive sensor 112 such that the center of the current I in the wires lies in the same sensitive plane E as the sensitive layer of the sensor 112. Thus the cross-talk can be strongly reduced or even completely eliminated.

The particular magnetic sensor design shown in FIG. 1 comprises a substrate 114 (e.g. Si) having on its top side regions R1 and R2 of different heights z₁ and z₂, respectively, wherein the GMR element 112 is placed on the first, higher region R1 and the conductors 111 and 113 are placed on the two second, lower regions R2. The thickness h of the conductors 111, 113 (measured in z-direction) can therefore be larger than the thickness d of the GMR element 112 as it is compensated by the height difference |z₁−z₂| of the two regions R1, R2 in such a way that the mid-plane of the conductor wires 111, 113 lies at the same height as the sensitive plane E of the GMR element 112. In the Figure, it is assumed for simplicity that said sensitive plane E coincides with the mid-plane of the GMR element 112, yielding the relation

|z₁−z₂|=(h−d)/2

for an ideal placement.

A microelectronic sensor device with the described “balanced placement” of the conductor wires and the magnetic sensor element can be achieved by various lithographical processes, for example:
1) Deposition of the sensor material on a substrate and simultaneously patterning of the sensor and etching into the substrate to the required depth. Subsequently the wire material is deposited and patterned.
2) Fabrication of buried wires with half of the required thickness. This could e.g. be the last stage of a CMOS process. After planarisation, deposition and patterning of magnetic material are done. Subsequently follows deposition and patterning of the second half of the wires. The thickness of the second wire layer can be tuned such that the cross-talk signal is eliminated.
3) Patterning of the substrate before the deposition of the wires and sensor, and subsequently deposition and patterning of the sensor and the wires.
4) Deposition and patterning of the wire material; deposition of an isolation material and the sensor material; subsequent patterning of the sensor material. In order to make contact between the wire and the sensor, also via-holes have to be made.

FIG. 2 shows consecutive steps of a first exemplary production process of a magnetic sensor device 200. This process is characterized in that only the (small) area fraction of the substrate surface underneath a region R1, which finally carries the GMR sensor 212, is left while the rest of the surface of the substrate S is etched away to a depth |z₁−z₂|. The first stage a) of this process comprises the deposition of the sensor material G (for example a layered sequence of the materials Ta, NiFe, IrMn, CoFe, Ru, CoFe, Cu, CoFe, NiFe, and Ta) on the substrate S and the deposition of a mask M1 over the first region R1. Next, the sensor material G and a part of the substrate S is etched away in the areas around the mask M1 (stage b). The etching mask M1 is then removed and the wire material W (for example Au) is deposited over the whole surface (stage c). In stage d), masks M2 are deposited over second regions R2 on the wire material. The wire material W is then etched away where it is not masked, resulting in stage e) in the final sensor device 200 that comprises a GMR sensor 212 and two conductor wires 211, 213 over the first region R1 and the two second regions R2, respectively, on the substrate 214.

FIG. 3 shows a variant of the aforementioned process which starts in stage a) with the deposition of a mask M1 over the first region R1 on the substrate S. The substrate S is then etched outside the mask Ml (stage b) such that an upstanding rim of height |z₁−z₂| remains. After removal of the mask M1, the sensor material G is deposited over the whole surface and a mask M2 is again placed over the first region R1 (stage c). In stage d), the sensor material G is etched away where it is not masked. After removal of the mask M2, the thick layer of wire material W is deposited over the whole surface and covered with masks M3 over two second regions R2 (stage e). Etching the wire material W away outside the masks M3 yields then in step f) the final sensor device 300 that comprises a GMR sensor 312 and two conductor wires 311, 313 over the first region R1 and the two second regions R2, respectively, on the substrate 314.

FIG. 4 shows another production process in which a fraction W1 of the wire material is disposed or buried in preformed channels in the substrate S (stage a). This may for example be done in the last stage of a CMOS process. After planarisation, the whole surface is in stage b) sequentially covered with the sensor material G and a second fraction W2 of wire material, and masks M1 are deposited over second regions R2. In stage c), the wire material W2 has been etched away where it was not masked and the masks have thereafter been removed. In stage d), new masks M2 and M3 have been placed over the first and a second regions R1 and R2, respectively, such that the sensor material G can now be etched away where it is not needed. This yields in stage e) the final sensor device 400 that comprises a GMR sensor 412 and two conductor wires 411, 413 over the first region R1 and the two second regions R2, respectively, on the substrate 414. The two conductor wires 411, 413 have in this case a layered structure with a bottom and a top layer of “pure” wire material and an intermediate layer of sensor material.

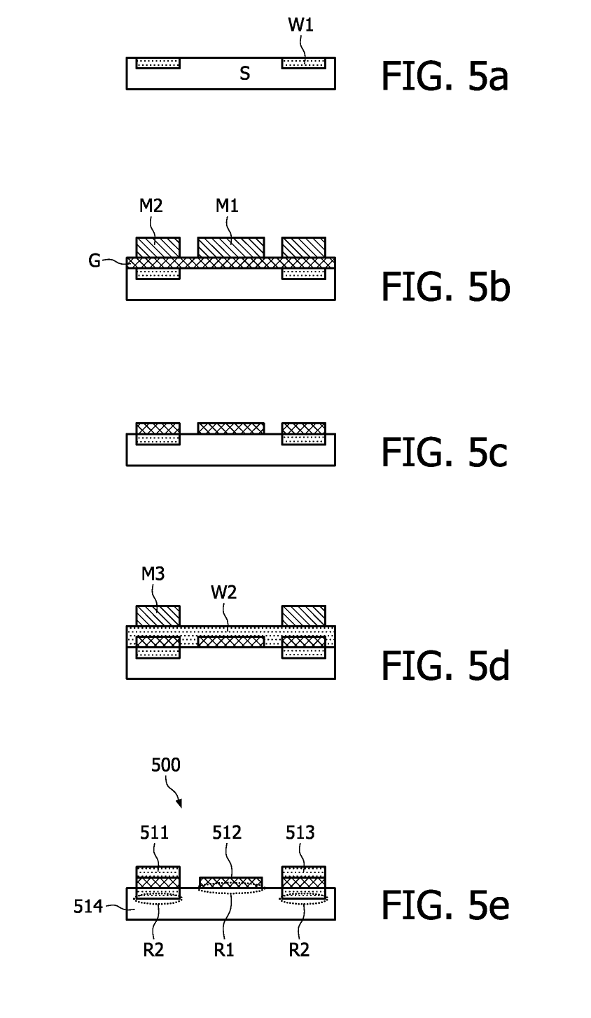

FIG. 5 shows a variant of the aforementioned process in which also a part W1 of the conductor wires is buried in the substrate S (stage a). In the next stage b), the sensor material G is deposited over the whole surface and masks M1 and M2 are placed over the first and second regions R1 and R2, respectively. In stage c), the excess sensor material G has been etched away and the masks have been removed. Next, the second part W2 of the wire material is deposited over the whole surface, and the second regions R2 are again covered by a mask M3 (stage d). The wire material W2 is then etched away where it is not masked and the masks are removed. This yields the final sensor device 500 of stage e) that comprises a GMR sensor 512 and two conductor wires 511, 513 over the first region R1 and the two second regions R2, respectively, on the substrate 514. As in the previous Figure, the conductor wires 511, 513 comprise three different layers.

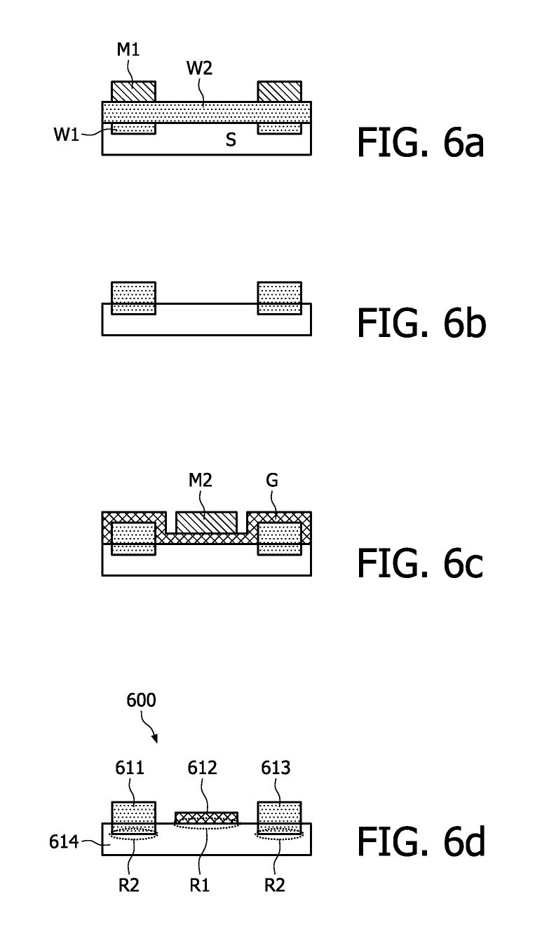

FIG. 6 shows a further variant of a production process that starts with a fraction W1 of wire material W buried in a substrate S. In stage a), these buried parts W1 have been covered by a second part W2 of wire material that extends over the whole surface and on which masks M1 have been placed over the second regions R2. In stage b), the second wire material W2 has been etched away where it was not masked and the masks have been removed. Next, the sensor material G is deposited over the whole surface and a mask M2 is placed over the first region R1 (stage c). The excess sensor material G is then etched away where it is not masked and the mask is removed. This yields in stage d) the final sensor device 600 that comprises a GMR sensor 612 and two conductor wires 611, 613 over the first region R1 and the two second regions R2, respectively, on the substrate 614. In this case, the conductor wires 611, 613 each consist of two blocks (typically of the same material, e.g. Au), from which one is buried in the substrate 614.

FIG. 7 illustrates an alternative production process that starts in stage a) with the deposition of a wire material W on a substrate S and the subsequent placement of masks M1 over second regions R2. In stage b), the unmasked wire material has been etched away and the mask has been removed. In stage c), an isolating material J (e.g. the same material as the substrate S) has been deposited over the whole surface and has then completely been covered by a sensor material G. In stage d), a mask M2 is deposited over the first region R1, and in stage e) the sensor material G has been etched away where it was not masked and the mask has been removed. This yields the final sensor device 700 that comprises a GMR sensor 712 and two conductor wires 711, 713 over the first region R1 and the two second regions R2, respectively, on the substrate 714. In contrast to the previous embodiments, the surface of the substrate S is left planar in this approach and the GMR sensor 712 is elevated by placing it on an additionally deposited (isolating) layer 715. To contact the wires 711 and 713, vias will typically have to be etched into the isolating layer 715 (not shown).

FIG. 8 shows the output signal s (e.g. a voltage drop) of the GMR sensor 212 in magnetic sensor devices 200 that were produced as shown in FIG. 2 with different depth |z₁−z₂| of etching into the substrate S. As no magnetic beads were present during the measurements, the diagram shows the magnetic cross-talk in dependence on the height difference |z₁−z₂| between the regions R1 and R2 on which the GMR sensor 212 and the excitation wires 611, 613 are placed, respectively. It can be seen that the cross-talk signal s changes from positive to negative by etching deeper into the substrate. By a careful tuning of the etching depth, the magnetic cross-talk signal can be completely eliminated.

While the invention was described above with reference to particular embodiments, various modifications and extensions are possible, for example:
In addition to molecular assays, also larger moieties can be detected with magnetic sensor devices according to the invention, e.g. cells, viruses, or fractions of cells or viruses, tissue extract, etc.
The detection can occur with or without scanning of the sensor element with respect to the biosensor surface.
Measurement data can be derived as an end-point measurement, as well as by recording signals kinetically or intermittently.
The magnetic particles serving as labels can be detected directly by the sensing method. As well, the particles can be further processed prior to detection. An example of further processing is that materials are added or that the (bio)chemical or physical properties of the label are modified to facilitate detection.
The device and method can be used with several biochemical assay types, e.g. binding/unbinding assay, sandwich assay, competition assay, displacement assay, enzymatic assay, etc.
The device and method are suited for sensor multiplexing (i.e. the parallel use of different sensors and sensor surfaces), label multiplexing (i.e. the parallel use of different types of labels) and chamber multiplexing (i.e. the parallel use of different reaction chambers).
The device and method can be used as rapid, robust, and easy to use point-of-care biosensors for small sample volumes. The reaction chamber can be a disposable item to be used with a compact reader, containing the one or more magnetic field generating means and one or more detection means. Also, the device, methods and systems of the present invention can be used in automated high-throughput testing. In this case, the reaction chamber is e.g. a well plate or cuvette, fitting into an automated instrument.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. A magnetic sensor device (100-700), comprising
a) a magnetic sensor element (112-712) that is sensitive for magnetic field components in a sensitive plane (E) and that has a first thickness (d) orthogonal to said sensitive plane;
b) at least one conductor (111-711, 113-713) for generating a magnetic excitation field (H) when a current (I) flows through it, said conductor having a second thickness (h) orthogonal to the sensitive plane (E) which is different from the first thickness (d),
wherein the conductor is arranged relative to the magnetic sensor element in such a way that the magnetic excitation field (H) is substantially perpendicular to the sensitive plane (E) within the magnetic sensor element.

2. The magnetic sensor device (100-700) according to claim 1,
characterized in that the magnetic sensor element (112-712) and the conductor (111-711, 113-713) are arranged on a first and a second region (R1, R2), respectively, of an isolating material (S, J), wherein said regions (R1, R2) belong to planes that have different distances from the sensitive plane (E).

3. The magnetic sensor device (400-600) according to claim 2,
characterized in that the second region (R2) lies on the bottom of a channel in a substrate (S).

4. The magnetic sensor device (100-700) according to claim 1,
characterized in that the shape of the magnetic sensor element (112-712) and/or of the conductor (111-711, 113-713) is symmetrical with respect to the sensitive plane (E).

5. The magnetic sensor device (100-700) according to claim 1,
characterized in that the first thickness (d) is less than 70%, preferably less than 50%, most preferably less than 10% of the second thickness (h).

6. The magnetic sensor device (100-700) according to claim 1,
characterized in that the magnetic sensor element comprises a coil, a Hall sensor, a planar Hall sensor, a flux gate sensor, a SQUID, a magnetic resonance sensor, a magneto-restrictive sensor, or a magneto-resistive element like a GMR (112-712), an AMR, or a TMR element.

7. A method for the production of a microelectronic magnetic sensor device (100-700) according to claim 1, comprising any sequence of the following steps:
a) the generation of a first and a second region (R1, R2) on an isolating material (S, J) at the surface of a substrate (S) that have different heights with respect to said surface;
b) the deposition of a first material (G) for the magnetic sensor element (112-712) over the first region (R1);
c) the deposition of a second material (W, W1, W2) for the conductor (111-711, 113-713) over the second region (R2).

8. The method according to claim 7,
characterized in that the first and the second region (R1, R2) are generated by etching an initially planar surface of the substrate (S).

9. The method according to claim 7,
characterized in that the first and the second region (R1, R2) are generated by deposition of insulator material (J) on a planar surface of the substrate (S).

10. The method according to claim 7,
characterized in that the first material (G) is deposited also over the second region (R2) and/or that the second material is deposited also over the first region (R1).

11. Use of the magnetic sensor device (100-700) according to claim 1 for molecular diagnostics, biological sample analysis, and/or chemical sample analysis, particularly the detection of small molecules
